(19) United States
(12) Patent Application Publication
(10) Pub. No.: US 2026/0114268 A1
(43) Pub. Date: Apr. 23, 2026

(54) THERMALLY CONDUCTIVE BILAYER FOR HEAT DISSIPATION IN A BACKSIDE POWER DISTRIBUTION NETWORK

(71) Applicant: QUALCOMM Incorporated, San Diego, CA (US)

(72) Inventors: Abhishek JAIN, San Diego, CA (US); Junjing BAO, San Diego, CA (US); John Jianhong ZHU, San Diego, CA (US); Giridhar NALLAPATI, San Diego, CA (US)

(21) Appl. No.: 18/924,868

(22) Filed: Oct. 23, 2024

(51) Int. Cl. H01L 23/532; H01L 21/768; H01L 23/373; H01L 23/528; H01L 29/06; H01L 29/423; H01L 29/775; H01L 29/78; H01L 29/786

(52) U.S. Cl. CPC H10W 20/47; H10W 20/435; H10W 40/25; H10D 30/43; H10D 30/62; H10D 30/6735; H10D 30/6757; H10D 62/121; H10W 20/01

(57) ABSTRACT

A chip includes an active device, a first backside thermally conductive layer, and a second backside thermally conductive layer, wherein the first backside thermally conductive layer is between the active device and the second backside thermally conductive layer. The chip also includes a first via electrically coupled to the active device, wherein the first via extends through the first backside thermally conductive layer, and a first metal path electrically coupled to the first via, wherein the first metal path extends through the second backside thermally conductive layer.

### BACKGROUND

### Field

Aspects of the present disclosure relate generally to semiconductors, and more particularly, to thermal dissipation in a chip.

### Background

A chip includes many active devices for performing various functions on the chip. The active devices may be implemented using gate-all-around field effect transistors (GAAFETs), fin field effect transistors (FinFETs), and/or other types of transistors. The chip may also include backside metal layers under the active devices. The backside metal layers may be patterned to provide a backside power distribution network (BSPDN) for delivering power to the active devices.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes an active device, a first backside thermally conductive layer, and a second backside thermally conductive layer, wherein the first backside thermally conductive layer is between the active device and the second backside thermally conductive layer. The chip also includes a first via electrically coupled to the active device, wherein the first via extends through the first backside thermally conductive layer, and a first metal path electrically coupled to the first via, wherein the first metal path extends through the second backside thermally conductive layer.

A second aspect relates to a chip. The chip includes an active device, a first backside thermally conductive layer, and a first backside dielectric layer, wherein the first backside thermally conductive layer is between the active device and the first backside dielectric layer. The chip also includes a first via electrically coupled to the active device, wherein the first via extends through the first backside thermally conductive layer, and a first metal path electrically coupled to the first via, wherein the first metal path extends through the first backside dielectric layer.

### BRIEF DESCRIPTION OF THE DRAWINGS

FIG. 1A shows a side view of an example of a chip including active devices and frontside layers according to certain aspects of the present disclosure.

FIG. 1B shows a side view of another example of a chip including active devices and frontside layers according to certain aspects of the present disclosure.

FIG. 2A shows a side view of an example of a chip including active devices, frontside layers, and backside layers according to certain aspects of the present disclosure.

FIG. 2B shows a side view of another example of a chip including active devices, frontside layers, and backside layers according to certain aspects of the present disclosure.

FIG. 3A shows an example of a chip after frontside processing according to certain aspects of the present disclosure.

FIG. 3B shows an example in which the chip of FIG. 3A is flipped over according to certain aspects of the present disclosure.

FIG. 3C shows an example in which a silicon substrate of the chip is removed according to certain aspects of the present disclosure.

FIG. 3D shows an example in which an etch stop layer and a backside interlayer dielectric (BS-ILD) are deposited on the backside of the chip according to certain aspects of the present disclosure.

FIG. 3E shows an example in which trenches are etched into the BS-ILD according to certain aspects of the present disclosure.

FIG. 3F shows an example in which metal is deposited into the trenches to form backside metal routing according to certain aspects of the present disclosure.

FIG. 3G shows an example in which the processes illustrated in FIGS. 3D to 3F are repeated to form an additional layer of backside metal routing according to certain aspects of the present disclosure.

FIG. 4A shows a side view of an example of a chip including active devices, frontside layers, and backside thermally conductive layers to enhance thermal dissipation according to certain aspects of the present disclosure.

FIG. 4B shows a side view of another example of a chip including active devices, frontside layers, and backside thermally conductive layers to enhance thermal dissipation according to certain aspects of the present disclosure.

FIG. 5A shows an example of a chip after frontside processing according to certain aspects of the present disclosure.

FIG. 5B shows an example in which the chip of FIG. 5A is flipped over according to certain aspects of the present disclosure.

FIG. 5C shows an example in which a silicon substrate of the chip is removed according to certain aspects of the present disclosure.

FIG. 5D shows an example in which backside thermally conductive layers are deposited on the backside of the chip according to certain aspects of the present disclosure.

FIG. 5E shows an example in which trenches are etched into the backside thermally conductive layers according to certain aspects of the present disclosure.

FIG. 5F shows an example in which metal is deposited into the trenches to form backside metal routing according to certain aspects of the present disclosure.

FIG. 5G shows an example in which the processes illustrated in FIGS. 5D to 5F are repeated to form an additional layer of backside metal routing according to certain aspects of the present disclosure.

FIG. 6A shows a side view of an example of a chip including active devices, frontside layers, backside thermally conductive layers, and backside dielectric layers according to certain aspects of the present disclosure.

FIG. 6B shows a side view of another example of a chip including active devices, frontside layers, backside thermally conductive layers, and backside dielectric layers according to certain aspects of the present disclosure.

FIG. 7A shows a side view of an example of a chip including active devices, frontside layers, and a backside thermally conductive layer according to certain aspects of the present disclosure.

FIG. 7B shows a side view of another example of a chip including active devices, frontside layers, and a backside thermally conductive layer according to certain aspects of the present disclosure.

FIG. 8A shows a perspective view of an example of active devices according to certain aspects of the present disclosure.

FIG. 8B shows the perspective view of FIG. 8A in which a gate in FIG. 8A is shown in phantom according to certain aspects of the present disclosure.

FIG. 9 shows a perspective view of another example of active devices according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

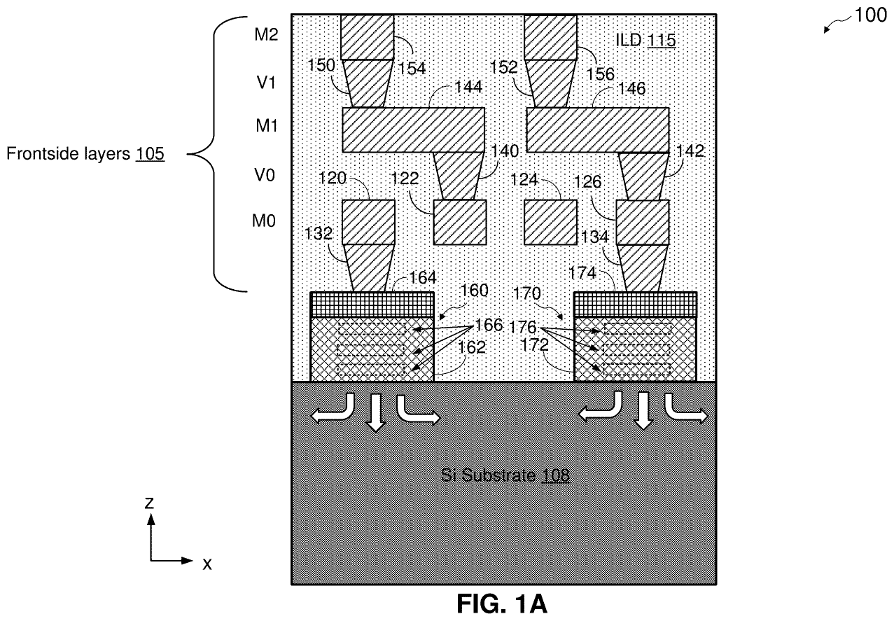

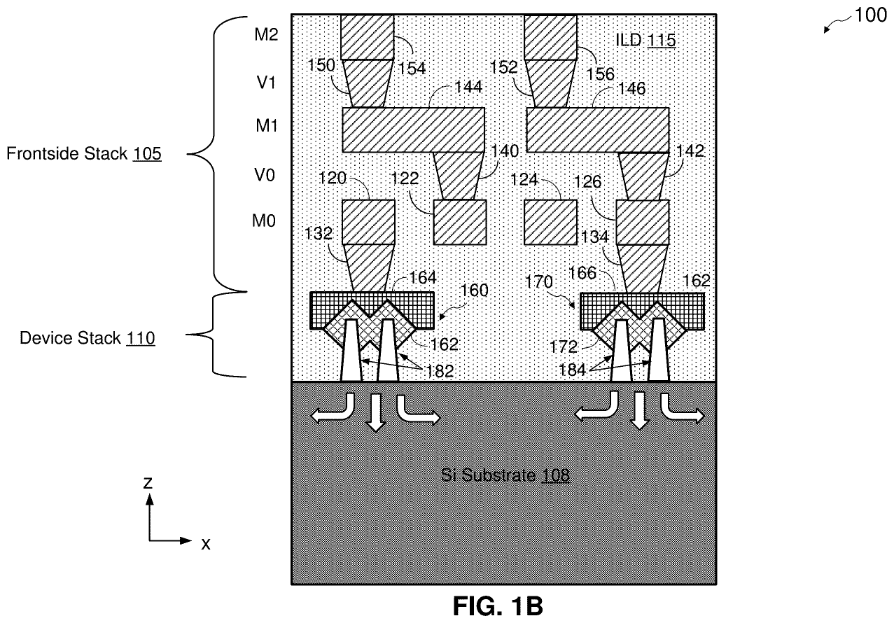

FIG. 1A shows a side view of an example of a chip 100 (e.g., a die) including active devices 160 and 170 and multiple frontside layers 105 (also referred to as the back end of line (BEOL)) according to certain aspects. As discussed further below, the active devices 160 and 170 may be implemented using a gate-all-around field effect transistor (FET) process, a fin field-effect transistor (FinFET) process, or another type of process. The frontside layers 105 are above active devices 160 and 170 in the z direction shown in FIG. 1A. The active devices 160 and 170 and the layers 105 may be formed on a silicon substrate 108.

In the example shown in FIG. 1A, the active devices 160 and 170 are implemented using a gate-all-around FET process. An example in which the active devices 160 and 170 are implemented using a FinFET process is discussed later with reference to FIG. 1B.

In the example shown in FIG. 1A, the active device 160 includes an active region including one or more nanosheets 166 stacked in the z direction and an epitaxial (epi) layer 162 coupled to the one or more nanosheets 166. The epi layer 162 may provide a source/drain of the active device 160, and the one or more nanosheets 166 may pass through a gate (not shown in FIG. 1A) of the active device 160 to provide one or more channels of the active device 160. As used herein, a “source/drain” refers to a source, a drain, or both. The chip 100 may also include a frontside contact 164 disposed on the epi layer 162 to provide a source/drain contact for the active device 160.

In this example, the active device 170 includes an active region including one or more nanosheets 176 stacked in the z direction and an epi layer 172 coupled to the one or more nanosheets 176. The epi layer 172 may provide a source/drain of the active device 170, and the one or more nanosheets 176 may pass through a gate (not shown in FIG. 1A) of the active device 170 to provide one or more channels of the active device 170. The chip 100 may also include a frontside contact 174 disposed on the epi layer 172 to provide a source/drain contact for the active device 170.

Each of the epi layers 162 and 172 may include epitaxially grown or deposited silicon, a silicon-based material (e.g., silicon-germanium), or any combination thereof. Each of the one or more nanosheets may include silicon (e.g., deposited silicon) and/or another material.

In the example shown in FIG. 1A, the frontside layers 105 include metal layers M0, M1, and M2 (also referred to as metal interconnects or another term). The metal layers M0, M1, and M2 may be patterned (e.g., using lithography and etching) to provide signal routing for the active devices 160 and 170 and other active devices (not shown in FIG. 1A) integrated on the chip 100. The metal layers M0, M1, and M2 may also be patterned to form a frontside power distribution network (FSPDN) including supply rails for distributing power to the active devices 160 and 170 and other active devices integrated on the chip 100.

In the example shown in FIG. 1A, the metal layer M0 is the bottom-most metal layer in the metal stack, the metal layer M1 is above the metal layer M0, and the metal layer M2 is above the metal layer M1. Although three metal layers (i.e., M0, M1, and M2) are shown in FIG. 1A, it is to be appreciated that the frontside layers 105 may include one or more additional metal layers above the metal layer M2. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0. Also, it is to be appreciated that one or more of the metal layers may be designated with a letter other than M in other examples. Accordingly, it is to be appreciated that the metal layers are not limited to the exemplary designations used in FIG. 1A. The chip 100 may also include an interlayer dielectric (ILD) 115 to provide electrical isolation between the metal layers. The ILD 115 may include silicon oxide and/or another dielectric material.

In the example shown in FIG. 1A, the metal layer M0 is patterned to form metal paths 120, 122, 124, and 126 (also referred to as metal wires), the metal layer M1 is patterned to form metal paths 144 and 146, and the metal layer M2 is patterned to form metal paths 154 and 156. The metal paths 120, 122, 124, and 126 in the metal layer M0 may extend in the y direction, the metal paths 144 and 146 in the metal layer M1 may extend in the x direction, and the metal paths 154 and 156 in the metal layer M2 may extend in the y direction. It is to be appreciated that the present disclosure is not limited to the exemplary metal routing shown in FIG. 1A.

In the example shown in FIG. 1A, the frontside layers 105 include vias V0 and vias V1, in which the vias V0 provide coupling between the metal layer M0 and the metal layer M1 and the vias V1 provide coupling between the metal layer M1 and the metal layer M2. In the example in FIG. 1A, the vias V0 include a via 140 coupling the metal path 122 and the metal path 144 and a vias 142 coupling the metal path 126 and the metal path 146. The vias V1 include a via 150 coupling the metal path 144 and the metal path 154 and a via 152 coupling the metal path 146 and the metal path 156.

In the example shown in FIG. 1A, the frontside layers 105 also includes a via 132 coupling the frontside contact 164 with the metal path 120 in the metal layer M0 and a via 134 coupling the frontside contact 174 with the metal path 126 in the metal layer M0. It is to be appreciated that the present disclosure is not limited to the exemplary vias shown in FIG. 1A.

FIG. 1B shows an example in which the active devices 160 and 170 are implemented using a FinFET process. In this example, the active region of the active device 160 includes one or more fins 182 with the epi layer 162 coupled to the one or more fins 182. The one or more fins 182 are orientated vertically and are spaced apart from one another in the horizontal direction (x direction in FIG. 1B). The epi layer 162 and/or the one or more fins 182 may provide the source/drain of the active device 160. The one or more fins 182 may also pass through the gate (not shown in FIG. 1A) of the active device 160 to provide the one or more channels of the active device 160. In this example, each fin may be surrounded on three sides by the gate.

In the example shown in FIG. 1B, the active region of the active device 170 includes one or more fins 184 with the epi layer 172 coupled to the one or more fins 184. The one or more fins 184 are orientated vertically and are spaced apart from one another in the horizontal direction (x direction in FIG. 1B). The epi layer 172 and/or the one or more fins 184 may provide the source/drain of the active device 170. The one or more fins 184 may also pass through the gate (not shown in FIG. 1B) of the active device 170 to provide the one or more channels of the active device 170.

The fins 182 and 184 may include silicon or another material. For example, in some implementations, the fins 182 and 184 may be fabricated by etching a top portion of the silicon substrate 108 to form the fins 182 and 184. However, it is to be appreciated that the present disclosure is not limited to this example.

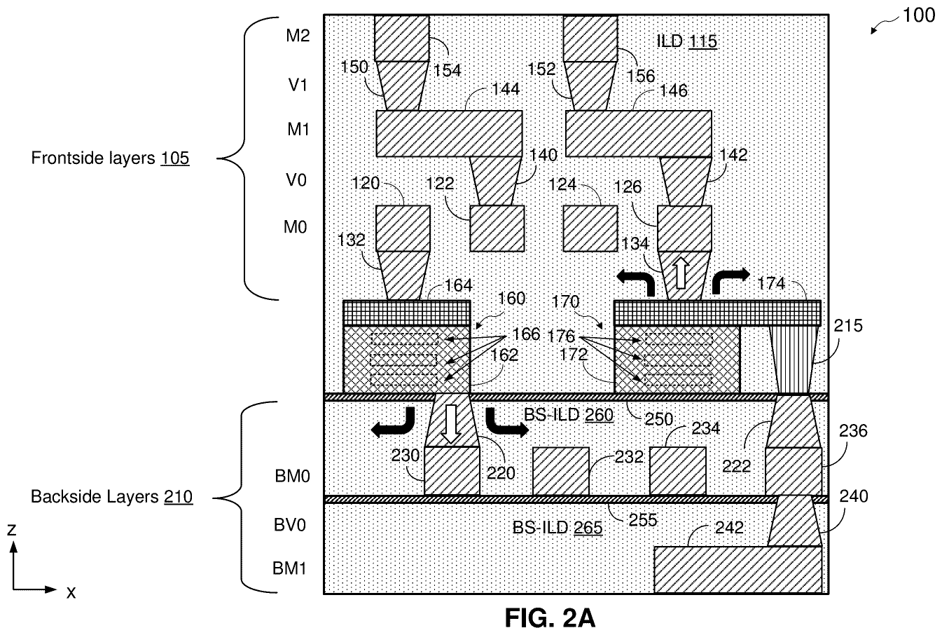

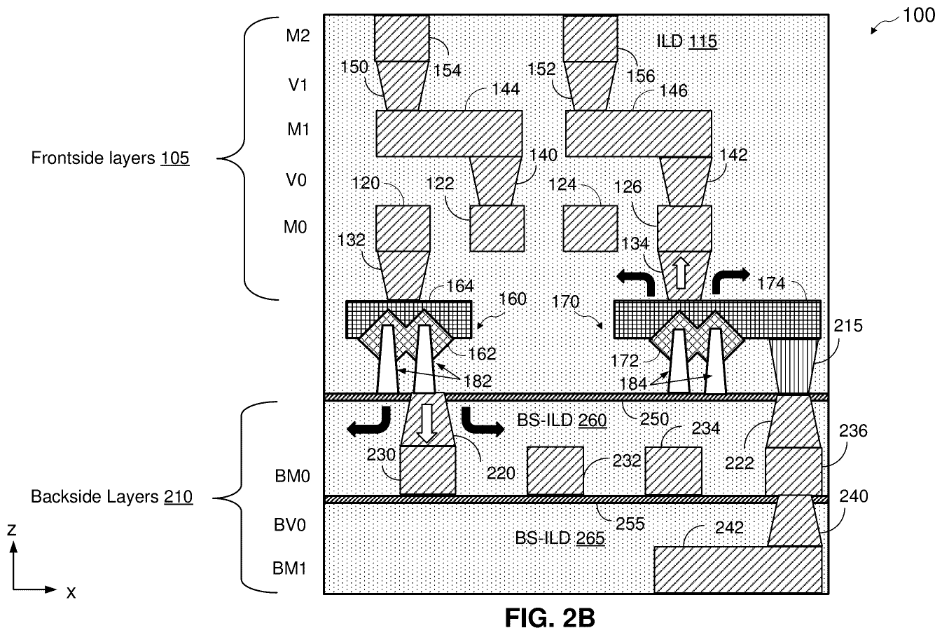

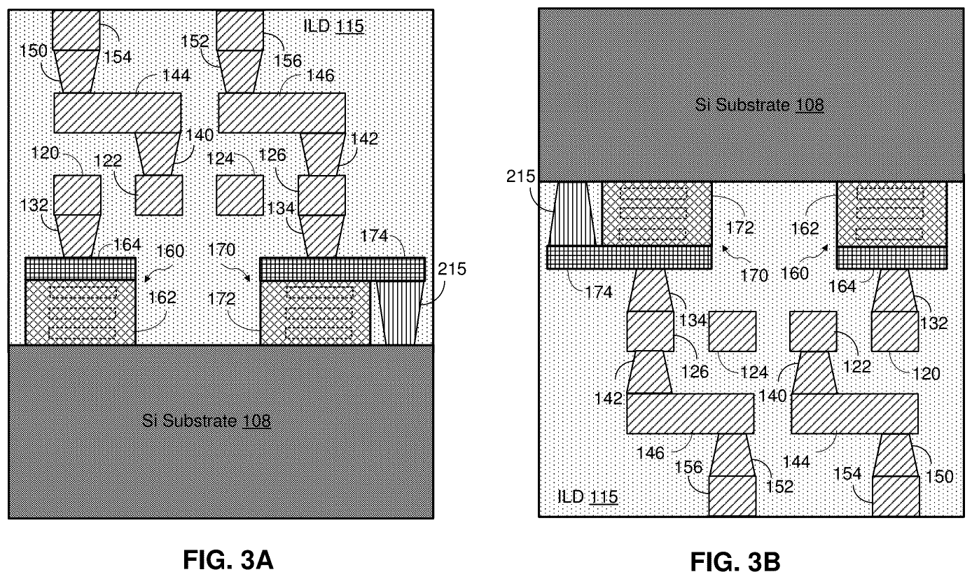

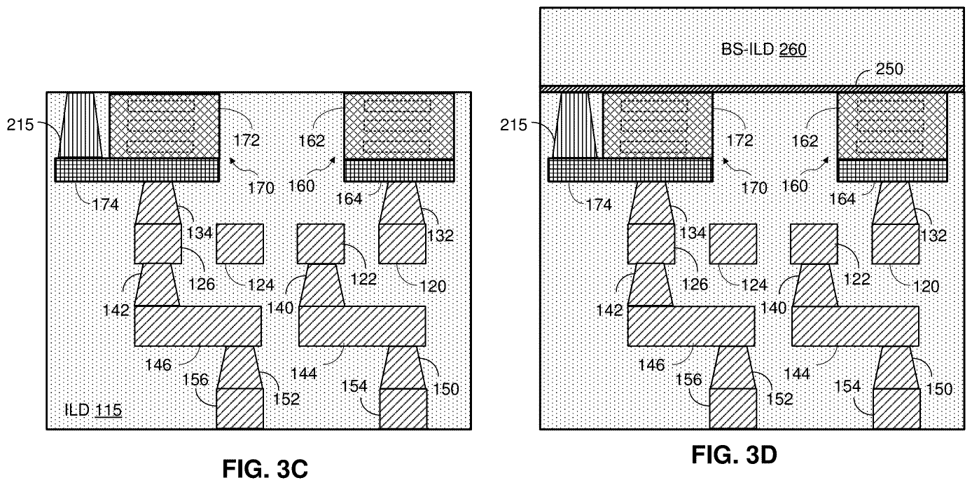

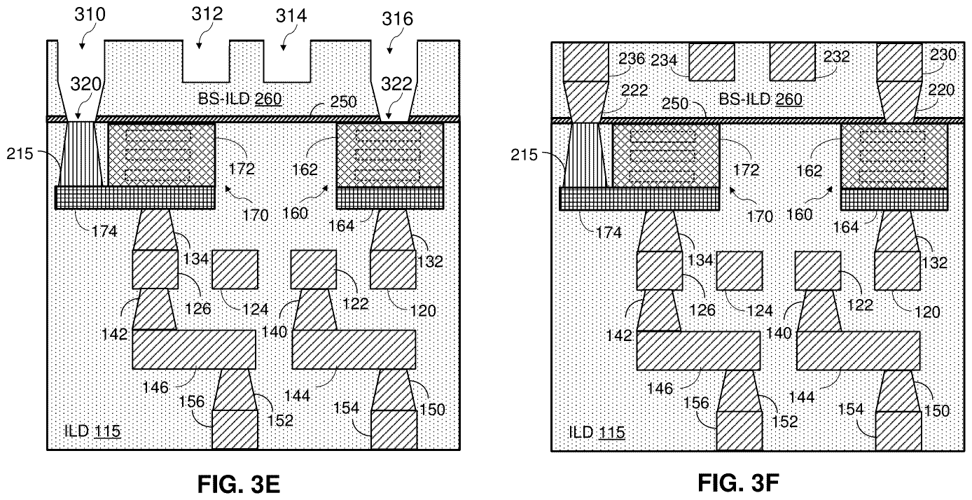

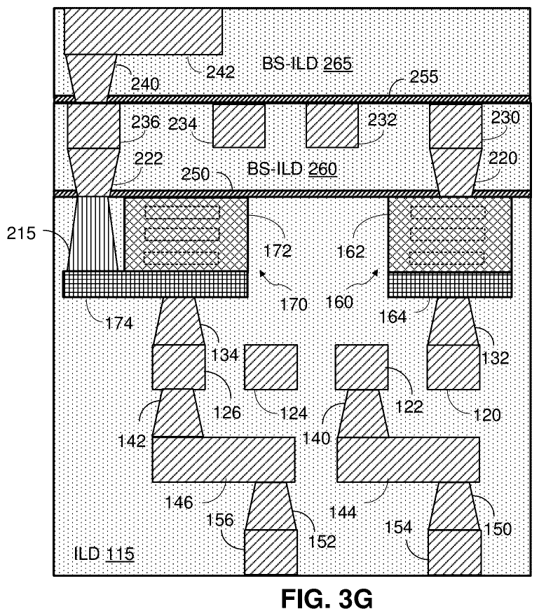

FIG. 2A shows an example in which the chip 100 includes backside layers 210 to facilitate backside routing. In this example, most or all of the silicon substrate 108 (not shown in FIG. 2A) may be removed to form backside layers 210 under the active devices 160 and 170. An exemplary backside process for forming the backside layers 210 is discussed further below with reference to FIGS. 3A to 3G. In the example shown in FIG. 2A, the active devices 160 and 170 are implemented with the gate-all-around FET process discussed above with reference to FIG. 1A.

In the example in FIG. 2A, the backside layers 210 include backside metal layers BM0 and BM1. The metal layers BM0 and BM1 may also be patterned (e.g., using lithography and etching) to form a backside power distribution network (BSPDN) including supply rails for distributing power to the active devices 160 and 170 and other active devices integrated on the chip 100.

In the example in FIG. 2A, the backside metal layer BM0 is the top-most metal layer in the backside metal stack, and the backside metal layer BM1 is below the backside metal layer BM0. Although two backside metal layers (i.e., BM0 and BM1) are shown in FIG. 2A, it is to be appreciated that the backside layers 210 may include one or more additional backside metal layers below the backside metal layer BM1. It is to be appreciated that the backside metal layers are not limited to the exemplary designations used in FIG. 2A.

In the example shown in FIG. 2A, the backside metal layer BM0 is patterned to form backside metal paths 230, 232, 234, and 236 and the backside metal layer BM1 is patterned to form backside metal path 242. The backside metal paths 230, 232, 234, and 236 in the backside metal layer BM0 may extend in the y direction to provide power routing in the y direction and the backside metal path 242 in backside metal layer BM1 may extend in the x direction to provide power routing in the x direction. In the example shown in FIG. 2A, the metal paths 232 and 234 may be coupled to and provide power routing for other active devices (not shown) on the chip 100. Also, the metal path 230 may be coupled to a metal path (not shown) in the backside metal layer BM1. It is to be appreciated that the present disclosure is not limited to the exemplary metal routing shown in FIG. 2A.

In the example shown in FIG. 2A, the backside layers 210 includes backside vias BV0 which provide coupling between the backside metal layer BM0 and the backside metal layer BM1. In this example, the backside vias BV0 include backside via 240 coupling the backside metal path 236 and the backside metal path 242.

In the example shown in FIG. 2A, the backside layers 210 also includes a via 220 coupling the source/drain (e.g., the epi layer 162) of the active device 160 with the metal path 230 in the backside metal layer BM0. In this example, the backside layers 210 also include a via 222 coupling the source/drain (e.g., the epi layer 172) of the active device 170 with the metal path 236 in the backside metal layer BM0. In the example shown in FIG. 2A, the via 222 is coupled to the epi layer 172 through the frontside contact 174 and a via 215 coupled between the frontside contact 174 and the via 222. In other implementations, the via 222 may be coupled to the backside (i.e., bottom) surface of the epi layer 172 with the via 215 omitted. It is to be appreciated that the present disclosure is not limited to the exemplary vias shown in FIG. 2A.

In the example shown in FIG. 2A, the chip 100 may also include a first backside interlayer dielectric (BS-ILD) 260 and a second BS-ILD 265 below the first BS-ILD 260. The chip 100 also includes a first etch stop layer 250 between the active devices 160 and 170 and the first BS-ILD 260 and a second etch stop layer 255 between the first BS-ILD 260 and the second BS-ILD 265. As discussed further below, the etch stop layers 250 and 255 are used as etch stops for the first BS-ILD 260 and the second BS-ILD 265, respectively, during backside process. In some implementations, the first BS-ILD 260 and the second BS-ILD 265 includes silicon oxide and/or another dielectric. In these implementations, the etch stop layers 250 and 255 may include silicon nitride or another material that can be used as a suitable etch stop for the first BS-ILD 260 and the second BS-ILD 265.

FIG. 2B shows an example of the backside layers 210 for the example where the active devices 160 and 170 are implemented using the FinFET process discussed above with reference to FIG. 1B. In this example, the via 220 may be coupled to the one or more fins 182 either directly or through a backside contact (not shown) disposed between the one or more fins 182 and the via 220. In the example shown in FIG. 2B, the via 222 is coupled to the one or more fins 184 through the frontside contact 174 and the via 215 coupled between the frontside contact 174 and the via 222. In other implementations, the via 222 may be coupled to the one or more fins 184 from the backside either directly or through a backside contact (not shown). It is to be appreciated that the present disclosure is not limited to the example shown in FIG. 2B.

In certain aspects, the frontside layers 105 are patterned to provide signal routing for the active devices 160 and 170 and other active devices (not shown) integrated on the chip 100. The backside layers 210 are patterned to form a backside power distribution network (BSPDN) to provide power to the active devices 160 and 170 and the other active devices from the backside. Moving the power distribution to the backside layers 210 helps reduce routing congestion compared with the case where the frontside layers 105 are used for both signal routing and power distribution. The reduced routing congestion allows the metal paths (also referred to as metal wires) of the BSPDN to be made wider, which reduces resistances (and hence IR drops) in the BSPDN.

FIGS. 3A to 3G illustrate an exemplary backside process for forming the backside layers 210 according to certain aspects. The exemplary backside process is shown for the example where the active devices 160 and 170 are implemented using the gate-all-around FET process. However, it is to be appreciated that the exemplary backside process is also applicable to the case where the active devices 160 and 170 are implemented using the FinFET process.

FIG. 3A shows an example of the chip 100 after formation of the active devices 160 and 170, the via 215, and the frontside layers 105 during frontside processing. In this example, the active devices 160 and 170 and the frontside layers 105 are fabricated on the silicon substrate 108.

After formation of the active devices 160 and 170 and the frontside layers 105, a carrier substrate may be bonded to the top of the chip 100 for structural support. The chip 100 may then be flipped to expose the backside of the silicon substrate 108, as shown in FIG. 3B. Note that the carrier substrate is not shown in FIG. 3B for ease of illustration.

In FIG. 3C, most or all of the silicon substrate 108 is removed to expose the backside of the active devices 160 and 170. For example, the silicon substrate 108 may be grounded and/or polished off (e.g., using chemical mechanical polishing (CMP)).

In FIG. 3D, the first etch stop layer 250 and the first BS-ILD 260 (e.g., silicon oxide) are deposited on the backside of the chip 100.

In FIG. 3E, the first BS-ILD 260 is etched to form trenches 310, 312, 314, and 316 for the vias 220 and 222 and the metal paths 230, 232, 234, and 236 in the backside metal layer BM0 (shown in FIGS. 2A and 2B). The areas of the first BS-ILD 260 that are etched to form the trenches 310, 312, 314, and 316 may be defined using lithography. In this example, the first etch stop layer 250 acts as an etch stop for the etching process used to etch the first BS-ILD 260 (i.e., the etch selectivity for the first BS-ILD 260 is high in relation to the etch stop layer 250).

After the etching of the first BS-ILD 260, holes 320 and 322 (i.e., openings) are etched through the etch stop layer 250 to expose the backsides of the active devices 160 and 170. In the example shown in FIG. 3E, the hole 320 provides access to the via 215 and the hole 322 exposes the backside of the source/drain (e.g., the epi layer 162) of the active device 160. In some implementations, the via 215 may be omitted and the hole 320 may expose the backside of the source/drain (e.g., the epi layer 172) of the active device 170.

FIG. 3F illustrates a backside metallization process in which metal is deposited in the trenches 310, 312, 314, and 316 and the holes 320 and 322 to form the vias 220 and 222 and the metal paths 230, 232, 234, and 236 in the backside metal layer BM0. The metal may include one or more different types of metal.

FIG. 3G shows an example in which the deposition, etching, and metallization processes illustrated in FIGS. 3D to 3F are repeated to form the second BS-ILD 265, the via 240, and the metal path 242 in the backside metal layer BM1.

During operation, the active devices 160 and 170 generate heat which needs to be dissipated to prevent overheating the chip 100. The heat generation increases as the active devices 160 and 170 operate at higher speeds. Overheating may cause damage to the active devices 160 and 170 and/or cause a temperature management circuit to shut down the active devices 160 and 170 or significantly reduce the speed of the active devices 160 and 170 to prevent damage.

For the case of frontside power distribution illustrated in FIGS. 1A and 1B, the silicon substrate 108 provides a good thermal conductor as well as a heat sink for dissipating heat from the active devices 160 and 170. FIGS. 1A and 1B show arrows indicating the heat flow from the active devices 160 and 170 to the silicon substrate 108.

For the case of backside power distribution illustrated in FIGS. 2A and 2B, the chip 100 may include several microns of dielectric layers (e.g., ILD and BS-ILD) on both the top and the bottom of the active devices 160 and 170. The dielectric layers provide poor thermal conduction in all directions compared with the silicon substrate 108 in FIGS. 1A and 1B. For example, for an oxide-based dielectric, the silicon substrate 108 may have a thermal conductivity that is 10 or more times higher than the thermal conductivity of the dielectric layers. In FIGS. 2A and 2B, the dark arrows indicate poor thermal conduction compared with the white arrows. Note that the lateral heat conduction paths from the active device 160 indicated by the arrows in FIGS. 2A and 2B also apply to the active device 170

As shown in FIGS. 2A and 2B, the lateral heat diffusion in the backside dielectric layers (e.g., the BS-ILDs 260 and 265) is poor. Since device hotspots are sensitive to lateral heat diffusion, the poor heat diffusion in the backside dielectric layers may cause the hot-spot temperatures of the active devices 160 and 170 to be significantly higher (e.g., 20 degrees higher) compared with the case where the chip 100 includes the silicon substrate 108 shown in FIGS. 1A and 1B.

Although the vias 220 and 222 (which include metal) provide good vertical heat conduction, the vias 220 and 220 have a very small cross-sectional area compared with the BS-ILD 260, which creates a bottleneck for heat dissipation.

To address the above, aspects of the present disclosure replace the oxide-based backside dielectric layers (e.g., the BS-ILDs 260 and 265) with backside thermally conductive layers. For example, the backside thermally conductive layers may include aluminum nitride (AlN) (˜200× thermal conductivity of silicon oxide) and/or silicon nitride (SiN) (˜10× thermal conductivity of silicon oxide). The backside thermally conductive layers improve lateral heat diffusion and lower hotspot temperatures while retaining the benefits of backside power distribution.

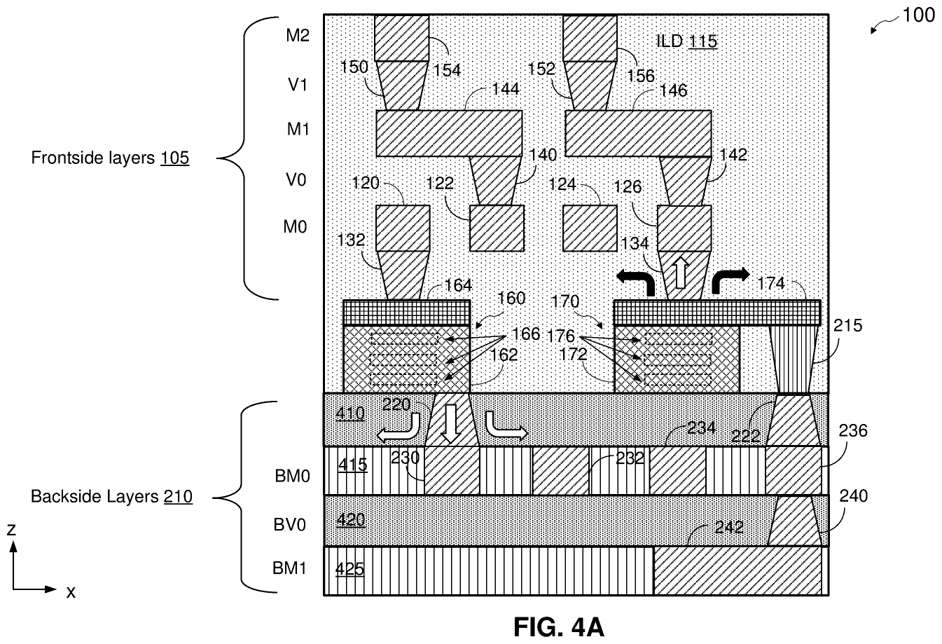

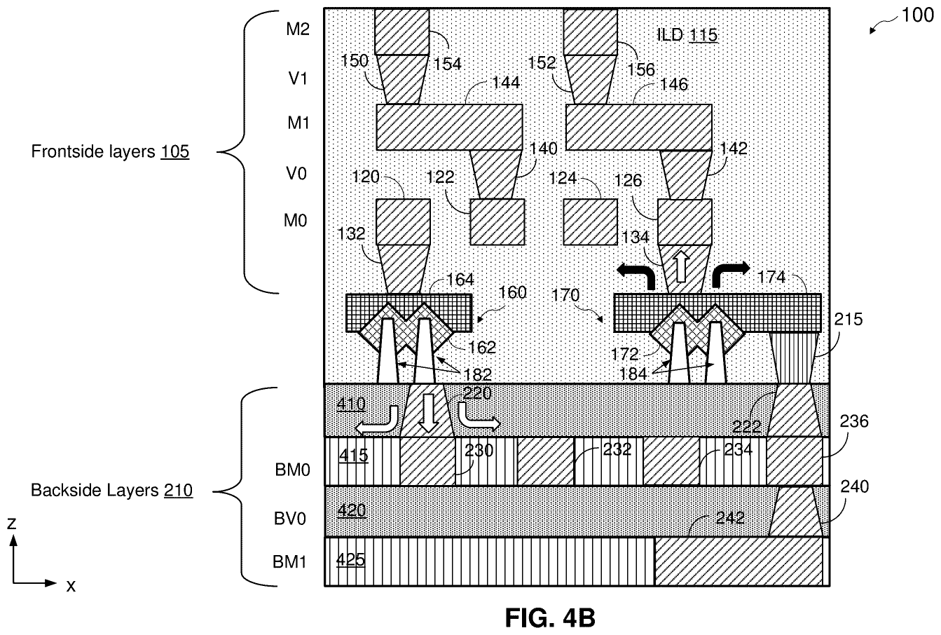

FIGS. 4A and 4B show examples in which the backside layers 210 include backside thermally conductive layers to improve heat dissipation according to certain aspects. In FIG. 4A, the active devices 160 and 170 are implemented using the gate-all-around FET process discussed above, and, in FIG. 4B, the active devices 160 and 170 are implemented using the FinFET process discussed above.

In the examples shown in FIGS. 4A and 4B, the backside thermally conductive layers include a first backside thermally conductive layer 410, a second backside thermally conductive layer 415, a third backside thermally conductive layer 420, and a fourth backside thermally conductive layer 425.

The first backside thermally conductive layer 410 may include AlN or another thermally conductive material. In the examples shown in FIGS. 4A and 4B, the first backside thermally conductive layer 410 is disposed between the active devices 160 and 170 and the second backside thermally conductive layer 415. The vias 220 and 222 extend through the first backside thermally conductive layer 410 to provide vertical power routing between the active devices 160 and 170 and backside metal layer BM0. In the examples shown in FIGS. 4A and 4B, the thickness of the first backside thermally conductive layer 410 is approximately equal to the height of the vias 220 and 222. In this example, the first backside thermally conductive layer 410 provides good lateral heat diffusion (i.e., heat spreading) next to the active devices 160 and 170, as indicated by the lateral arrows in FIGS. 4A and 4B.

The second backside thermally conductive layer 415 may include SiN or another thermally conductive material. In the examples shown in FIGS. 4A and 4B, the second backside thermally conductive layer 415 is disposed between the first backside thermally conductive layer 410 and the third backside thermally conductive layer 420. The metal paths 230, 232, 234, and 236 extend through the second backside thermally conductive layer 415 to provide lateral power routing (e.g., routing in the y direction). In the examples shown in FIGS. 4A and 4B, the thickness of the second backside thermally conductive layer 415 is approximately equal to the height of the metal paths 230, 232, 234, and 236. The second backside thermally conductive layer 415 provides good lateral heat diffusion from the metal paths 230, 232, 234, and 236 as well as from the first backside thermally conductive layer 410.

The third backside thermally conductive layer 420 may include AlN or another thermally conductive material. In the examples shown in FIGS. 4A and 4B, the third backside thermally conductive layer 420 is disposed between the second backside thermally conductive layer 415 and the fourth backside thermally conductive layer 425. The via 240 extends through the third backside thermally conductive layer 420 to provide vertical power routing. The thickness of the third backside thermally conductive layer 420 may be approximately equal to the height of the via 240. In this example, the third backside thermally conductive layer 420 provides good lateral heat diffusion from the via 240 as well as from the second backside thermally conductive layer 415.

The fourth backside thermally conductive layer 425 may include SiN or another thermally conductive material. In the examples shown in FIGS. 4A and 4B, the fourth backside thermally conductive layer 425 lies below the third backside thermally conductive layer 420. The metal path 242 extends through the fourth backside thermally conductive layer 425 to provide lateral power routing (e.g., routing in the x direction). The thickness of the fourth backside thermally conductive layer 425 may be approximately equal to the height of the metal path 242. In this example, the fourth backside thermally conductive layer 425 provides good lateral heat diffusion from the metal path 242 as well as from the third backside thermally conductive layer 420.

It is to be appreciated that the chip 100 may include additional backside metal layers below backside metal layer BM1 and additional backside thermally conductive layers below the fourth backside thermally conductive layer 425 for heat dissipation.

In the examples shown in FIGS. 4A and 4B, the backside thermally conductive layers 410, 415, 420, and 416 significantly improve thermal dissipation in the backside layers 210 compared with the BS-ILDs 260 and 265 shown in FIGS. 2A and 2B.

In certain aspects, the first backside thermally conductive layer 410 includes AlN to provide good lateral thermal diffusion for the active devices 160 and 170. As discussed above, the vias 220 and 222 have a very low area density which creates a bottleneck for heat conduction that increases hotspot temperatures. In this example, the first backside thermally conductive layer 410 provides good lateral heat diffusion next to the active devices 160 and 170 to lower hotspot temperatures. For example, AlN may have a thermal conductivity that is approximately 200 times greater than the thermal conductivity of silicon oxide. However, it is to be appreciated that the first backside thermally conductive layer 410 is not limited to the example of AlN and that other thermally conductive materials may be used.

In certain aspects, the second backside thermally conductive layer 415 includes SiN to provide good thermal diffusion from the first backside thermally conductive layer 410. For example, SiN may have a thermal conductivity that is approximately 10 times greater than the thermal conductivity of silicon oxide. While the thermal conductivity of SiN may not be as high as AlN, lateral trenches may be easily etched into SiN (e.g. using plasma dry etch, reactive-ion etch (RIE), etc.) to form the metal paths 230, 232, 234, and 236. Also, the area density of the metal paths 230, 232, 234, and 236 is higher than the area density of the vias 220 and 222 since the metal paths 230, 232, 234, and 236 provide lateral power routing. Because of the higher area density of the metal paths 230, 232, 234, and 236, the metal paths 230, 232, 234, and 236 provide a larger area for heat dissipation than the vias 220 and 222. It is to be appreciated that the second backside thermally conductive layer 415 is not limited to the example of SiN and that other thermally conductive materials may be used such as silicon carbon nitride (SiCₓN₁₋ₓ) where x indicates the proportion of carbon and 1-x indicates the proportion of nitride. In these aspects, the backside thermally conductive layers 410 and 415 improve lateral heat diffusion next to the active devices 160 and 170 in the via layer as well as the backside metal layer BM0, which lowers hotspot temperatures.

In certain aspects, the backside thermally conductive layers 410, 415, 420, and 425 include alternating layers of AlN and SiN that provide lateral heat diffusion in which the backside vias (e.g., vias 220, 222, and 240) extend through the AlN layers and the backside metal paths (e.g., metal paths 230, 232, 234, 236, and 242) extend through the SiN layers. However, the present disclosure is not limited to this example. For example, in other implementations, the SiN layers may be replaced with layers of silicon carbon nitride (SiCₓN₁₋ₓ) or another thermally conductive material.

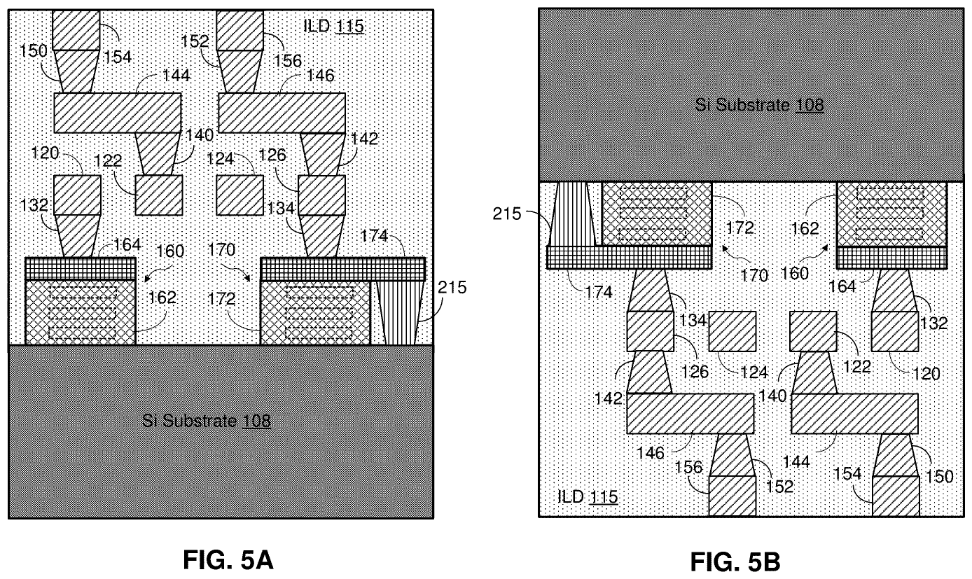

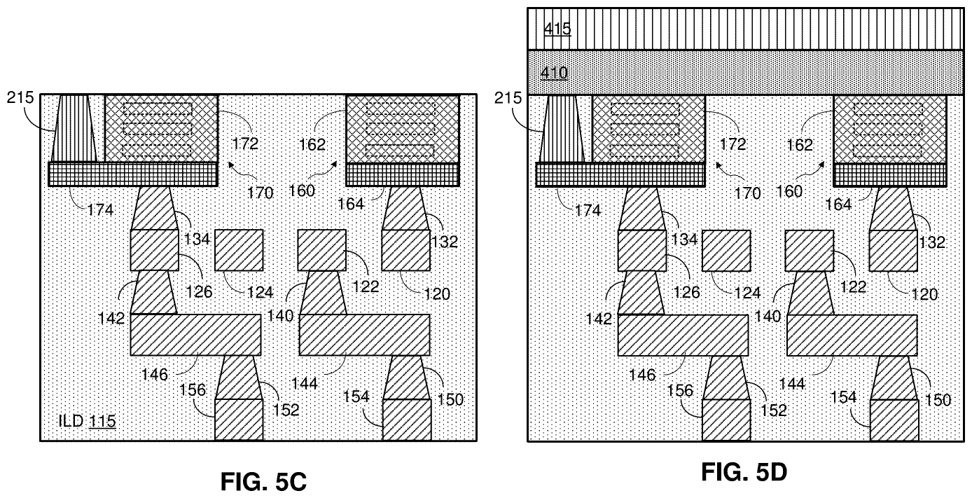

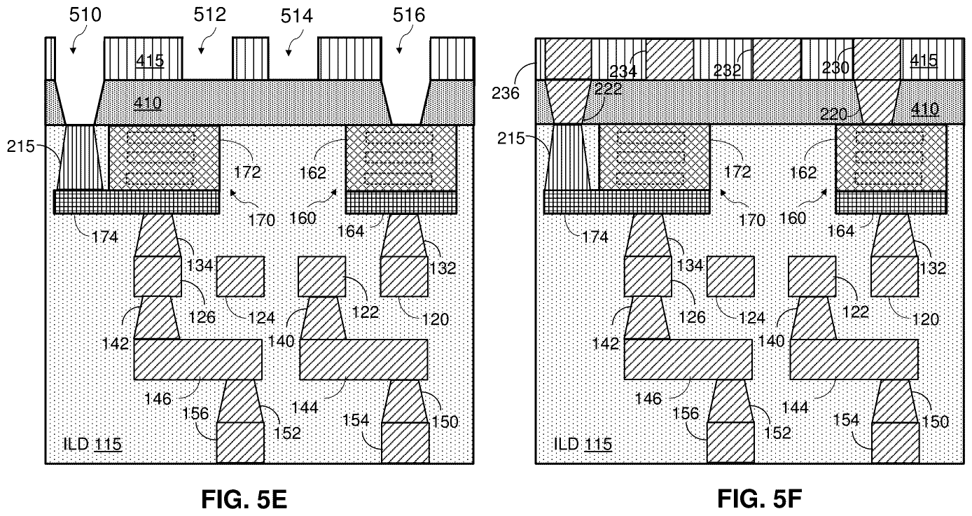

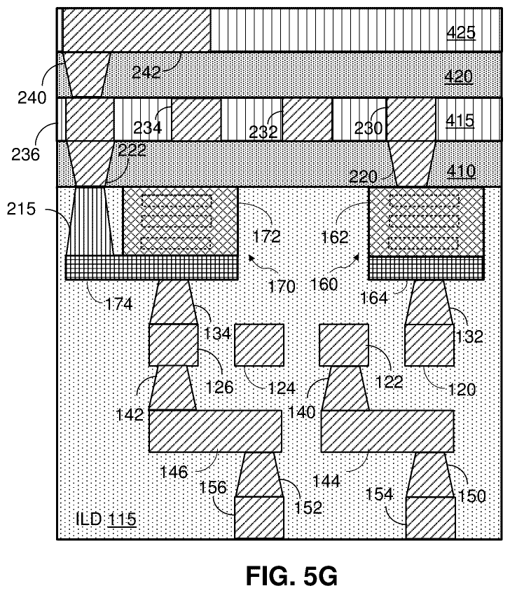

FIGS. 5A to 5G illustrate an exemplary backside process for forming the backside layers 210 including the backside thermally conductive layers 410, 415, 420, and 425 according to certain aspects. The exemplary backside process is shown for the example where the active devices 160 and 170 are implemented using the gate-all-around FET process. However, it is to be appreciated that the exemplary backside process is also applicable to the case where the active devices 160 and 170 are implemented using the FinFET process.

FIG. 5A shows an example of the chip 100 after formation of the active devices 160 and 170, the via 215, and the frontside layers 105 during frontside processing. In this example, the active devices 160 and 170 and the frontside layers 105 are fabricated on the silicon substrate 108.

After formation of the active devices 160 and 170 and the frontside layers 105, a carrier substrate may be bonded to the top of the chip 100 for structural support. The chip 100 may then be flipped to expose the backside of the silicon substrate 108, as shown in FIG. 5B. Note that the carrier substrate is not shown in FIG. 5B for ease of illustration.

In FIG. 5C, most or all of the silicon substrate 108 is removed to expose the backside of the active devices 160 and 170. For example, the silicon substrate 108 may be grounded and/or polished off (e.g., using chemical mechanical polishing (CMP)).

In FIG. 5D, the backside thermally conductive layers 410 and 415 are deposited on the backside of the chip 100.

In FIG. 5E, the backside thermally conductive layers 410 and 415 are etched to form trenches 510 and 516 and the second backside thermally conductive layer 415 is etched to form the trenches 512 and 514. The backside thermally conductive layers 410 and 415 may be etched using plasma dry etch, reactive-ion etch (RIE), etc. The areas of the backside thermally conductive layers 410 and 415 that are etched may be defined using lithography.

FIG. 5F illustrates a backside metallization process in which metal is deposited in the trenches 510, 512, 514, and 516 to form the vias 220 and 222 and the metal paths 230, 232, 234, and 236 in the backside metal layer BM0. The metal may include one or more different types of metals.

FIG. 5G shows an example in which the deposition, etching, and metallization processes illustrated in FIGS. 5D to 5F are repeated to form the backside thermally conductive layers 420 and 425, the via 240, and the metal path 242 in the backside metal layer BM1.

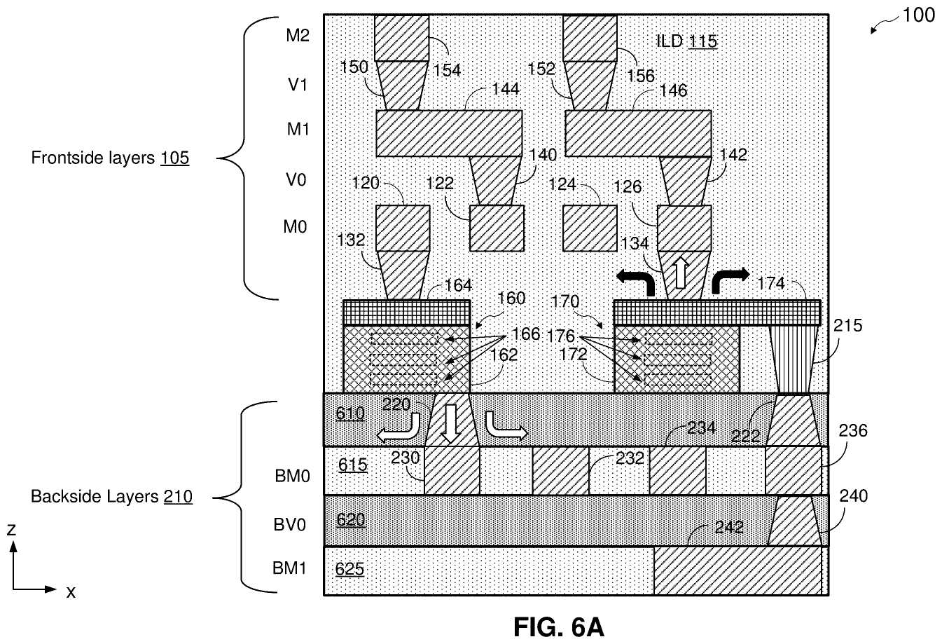

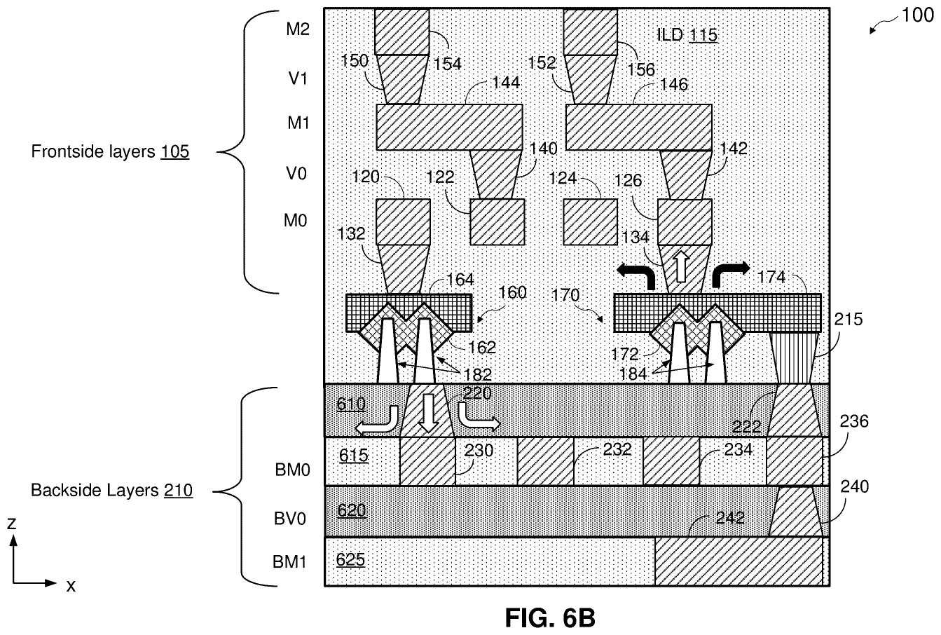

FIGS. 6A and 6B show examples in which the backside layers 210 include alternating layers of thermally conductive material and dielectric material according to certain aspects. In FIG. 6A, the active devices 160 and 170 are implemented using the gate-all-around FET process discussed above, and, in FIG. 6B, the active devices 160 and 170 are implemented using the FinFET process discussed above.

In the examples shown in FIGS. 6A and 6B, the backside layers 210 include a first backside thermally conductive layer 610, a first backside dielectric layer 615, a second backside thermally conductive layer 620, and a second backside dielectric layer 625.

The first backside thermally conductive layer 610 may include AlN or another thermally conductive material (e.g., SiN or SiCₓN₁₋ₓ). In the examples shown in FIGS. 6A and 6B, the first backside thermally conductive layer 610 is disposed between the active devices 160 and 170 and the first backside dielectric layer 615. The vias 220 and 222 extend through the first backside thermally conductive layer 610 to provide vertical power routing between the active devices 160 and 170 and backside metal layer BM0.

In the examples shown in FIGS. 6A and 6B, the thickness of the first backside thermally conductive layer 610 is approximately equal to the height of the vias 220 and 222. In this example, the first backside thermally conductive layer 610 provides good lateral heat diffusion next to the active devices 160 and 170, as indicated by the lateral arrows in FIGS. 6A and 6B. As discussed above, the vias 220 and 222 have a very low area density which creates a bottleneck for heat conduction that increases hotspot temperatures. In this example, the first backside thermally conductive layer 610 provides good lateral heat diffusion next to the active devices 160 and 170 to lower hotspot temperatures.

The first backside dielectric layer 615 may include silicon oxide or another oxide-based dielectric material. In the examples shown in FIGS. 6A and 6B, the first backside dielectric layer 615 is disposed between the first backside thermally conductive layer 610 and the second backside thermally conductive layer 620. The metal paths 230, 232, 234, and 236 extend through the first backside dielectric layer 615 to provide lateral power routing. The thickness of the first backside dielectric layer 615 may be approximately equal to the height of the metal paths 230, 232, 234, and 236. For the example where the first backside dielectric layer 615 includes silicon oxide, the first backside dielectric layer 615 may have a lower dielectric constant than the first backside thermally conductive layer 610 which lowers parasitic capacitances between the metal paths 230, 232, 234, and 236.

The second backside thermally conductive layer 620 may include AlN or another thermally conductive material (e.g., SiN or SiCₓN₁₋ₓ). In the examples shown in FIGS. 6A and 6B, the second backside thermally conductive layer 620 is disposed between the first backside dielectric layer 615 and the second backside dielectric layer 625. The via 240 extends through the second backside thermally conductive layer 620 to provide vertical power routing. The thickness of the second backside thermally conductive layer 620 may be approximately equal to the height of the via 240. The second backside thermally conductive layer 620 provides good lateral heat diffusion from the via 240.

The second backside dielectric layer 625 may include silicon oxide or another oxide-based dielectric material. In the examples shown in FIGS. 6A and 6B, the second backside dielectric layer 625 lies below the second backside thermally conductive layer 620. The metal path 242 extends through the second backside dielectric layer 625. The thickness of the second backside dielectric layer 625 may be approximately equal to the height of the metal path 242.

It is to be appreciated that the chip 100 may include additional backside metal layers below backside metal layer BM1, additional backside thermally conductive layers, and additional backside dielectric layers.

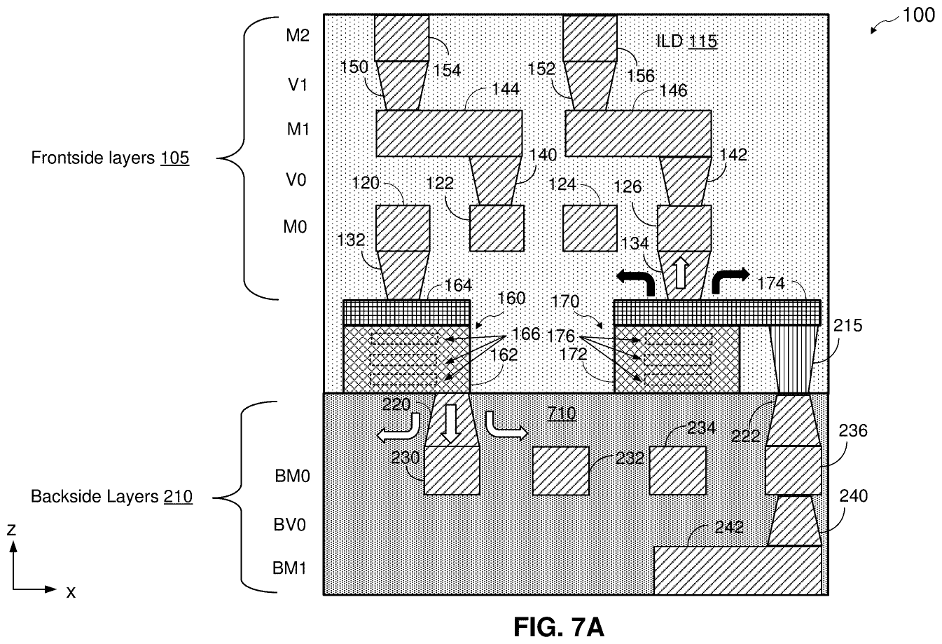

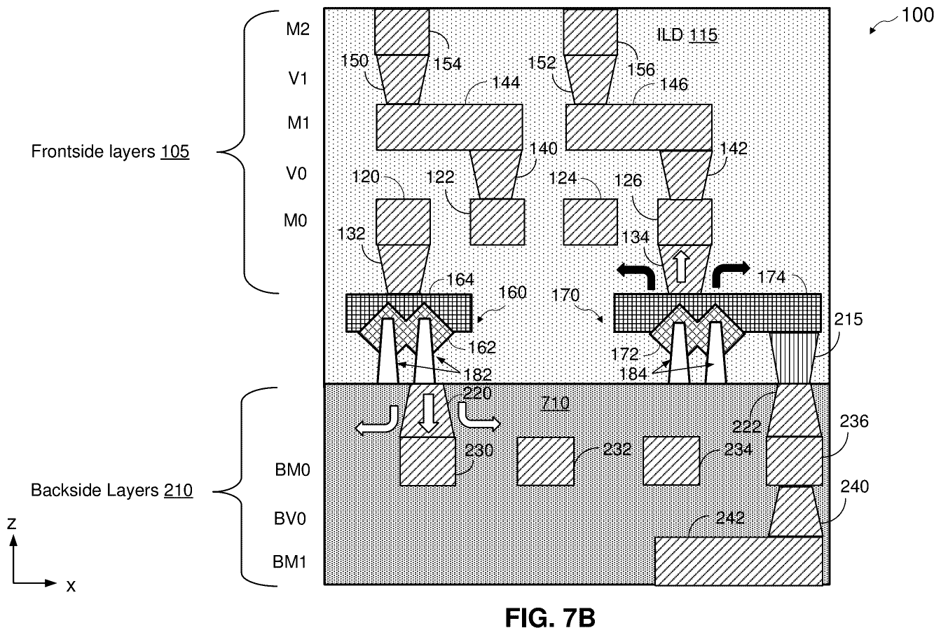

FIGS. 7A and 7B show examples in which the backside layers 210 include a backside thermally conductive layer 710 according to certain aspects. In FIG. 7A, the active devices 160 and 170 are implemented using the gate-all-around FET process discussed above, and, in FIG. 7B, the active devices 160 and 170 are implemented using the FinFET process discussed above.

In the examples shown in FIGS. 7A and 7B, the backside thermally conductive layer 710 may include AlN or another thermally conductive material (e.g., SiN or SiCₓN₁₋ₓ). In these examples, the vias 220, 222, and 240 and the metal paths 230, 232, 234, 236, and 242 of the BSPDN extend through the backside thermally conductive layer 710 for enhanced heat dissipation.

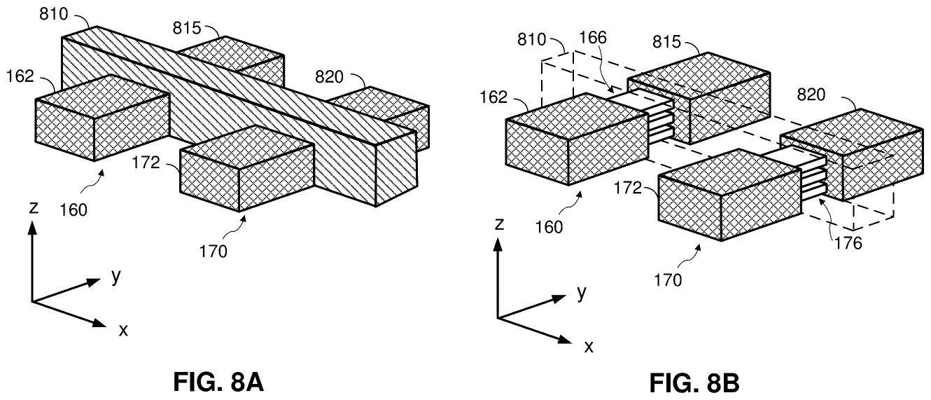

FIG. 8A shows an example of a perspective view of the active devices 160 and 170 according to certain aspects. In this example, the active devices 160 and 170 are implemented using the gate-all-around FET process.

In the example in FIG. 8A, the active device 160 includes the epi layer 162 and the one or more nanosheets 166 discussed above. The active device 160 also includes a gate 810 and another epi layer 815. In this example, the gate 810 is disposed between the epi layers 162 and 815. The one or more nanosheets 166 are coupled between the epi layers 162 and 815 and pass through the gate 810 to provide the one or more channels of the active device 160. FIG. 8B shows the gate 810 in phantom to show the one or more nanosheets 166 passing through the gate 810. In this example, the epi layer 162 corresponds to a first source/drain of the active device 160 and the epi layer 815 corresponds to a second source/drain of the active device 160.

In the example in FIG. 8A, the active device 170 includes the epi layer 172 and the one or more nanosheets 176 discussed above. The active device 170 also includes the gate 810 and another epi layer 820. In this example, the gate 810 is disposed between the epi layers 172 and 820. The one or more nanosheets 176 are coupled between the epi layers 172 and 820 and pass through the gate 810 to provide the one or more channels of the active device 170. FIG. 8B shows the gate 810 in phantom to show the one or more nanosheets 176 passing through the gate 810. In this example, the epi layer 172 corresponds to a first source/drain of the active device 170 and the epi layer 820 corresponds to a second source/drain of the active device 170.

In the example shown in FIG. 8A, the active devices 160 and 170 share the gate 810. However, it is to be appreciated that, in other implementations, the gate 810 may be cut between the active devices 160 and 170 to provide the active devices 160 and 170 with separate gates.

It is to be appreciated that, in some implementations, the backside via 220 may be coupled to the epi layer 162 of the active device 160 and the frontside via 132 may be coupled to the epi layer 815 of the active device 160, or vice versa. It is also to be appreciated that, in some implementations, the backside via 222 may be coupled to the epi layer 172 of the active device 170 and the frontside via 134 may be coupled to the epi layer 820 of the active device 170, or vice versa.

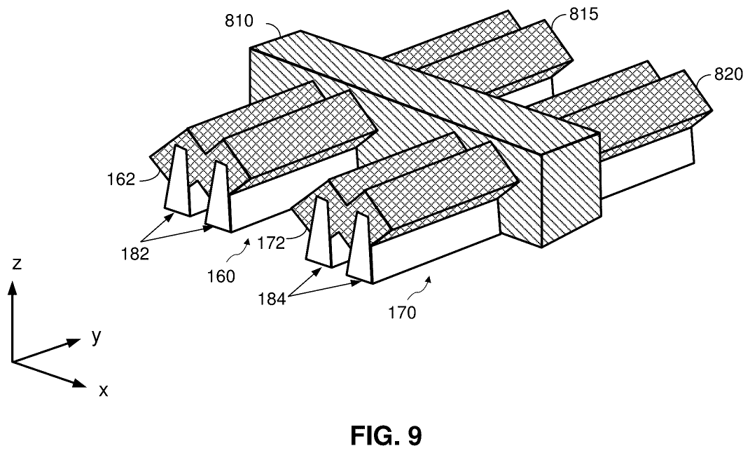

FIG. 9 shows another example of a perspective view of the active devices 160 and 170 according to certain aspects. In this example, the active devices 160 and 170 are implemented using the FinFET process.

In the example in FIG. 9, the active device 160 includes the epi layers 162 and 815, the gate 810, and the one or more fins 182 discussed above. In this example, the one or more fins 182 pass through the gate 810 to provide the one or more channels of the active device 160. The epi layer 162 is disposed on a first portion of the one or more fins 182, the epi layer 815 is disposed on a second portion of the one or more fins 182, and the gate 810 is disposed between the epi layers 162 and 815.

In the example in FIG. 9, the active device 170 includes the epi layers 172 and 820, the gate 810, and the one or more fins 184 discussed above. In this example, the one or more fins 184 pass through the gate 810 to provide the one or more channels of the active device 170. The epi layer 172 is disposed on a first portion of the one or more fins 184, the epi layer 820 is disposed on a second portion of the one or more fins 184, and the gate 810 is disposed between the epi layers 172 and 820.

In the example shown in FIG. 9, the active devices 160 and 170 share the gate 810. However, it is to be appreciated that, in other implementations, the gate 810 may be cut between the active devices 160 and 170 to provide the active devices 160 and 170 with separate gates.

It is to be appreciated that, in some implementations, the backside via 220 may be coupled to the epi layer 162 of the active device 160 and the frontside via 132 may be coupled to the epi layer 815 of the active device 160, or vice versa. It is also to be appreciated that, in some implementations, the backside via 222 may be coupled to the epi layer 172 of the active device 170 and the frontside via 134 may be coupled to the epi layer 820 of the active device 170, or vice versa.

In the examples discussed above, each of the active devices 160 and 170 includes one or more nanosheets or one or more fins to provide one or more channels. However, it is to be appreciated that the active devices 160 and 170 are not limited to these examples and that other types of channels may be used. As used herein, a “channel” is a structure that conducts current between a first source/drain and a second source/drain of an active device (e.g., a transistor).

Implementation examples are described in the following numbered clauses:
1. A chip, comprising:
   an active device;
   a first backside thermally conductive layer;
   a second backside thermally conductive layer, wherein the first backside thermally conductive layer is between the active device and the second backside thermally conductive layer;
   a first via electrically coupled to the active device, wherein the first via extends through the first backside thermally conductive layer; and
   a first metal path electrically coupled to the first via, wherein the first metal path extends through the second backside thermally conductive layer.
2. The chip of clause 1, wherein the first backside thermally conductive layer comprises aluminum nitride.
3. The chip of clause 2, wherein the second backside thermally conductive layer comprises silicon nitride or silicon carbon nitride.
4. The chip of any one of clauses 1 to 3, wherein a thickness of the first backside thermally conductive layer is approximately equal to a height of the first via.
5. The chip of clause 4, wherein a thickness of the second backside thermally conductive layer is approximately equal to a height of the first metal path.
6. The chip of any one of clauses 1 to 5, wherein the first via and the first metal path are part of a backside power distribution network configured to provide the active device with a supply voltage.
7. The chip of clause 6, further comprising frontside signal routing electrically coupled to the active device.
8. The chip of clause 7, wherein the first via is electrically coupled to a first source/drain of the active device and the frontside signal routing is electrically coupled to a second source/drain of the active device.
9. The chip of clause 8, wherein the active device includes a gate and one or more channels passing through the gate and electrically coupled between the first source/drain and the second source/drain.
10. The chip of clause 9, wherein the one or more channels include one or more nanosheets or one or more fins.
11. The chip of any one of clauses 7 to 10, wherein the active device is between the frontside routing and the first backside thermally conductive layer.
12. The chip of any one of clauses 1 to 11, further comprising:
   a third backside thermally conductive layer;
   a fourth backside thermally conductive layer, wherein the third backside thermally conductive layer is between the second backside thermally conductive layer and the fourth backside thermally conductive layer;
   a second via electrically coupled to the first metal path, wherein the second via extends through the third backside thermally conductive layer; and
   a second metal path electrically coupled to the second via, wherein the second metal path extends through the fourth backside thermally conductive layer.
13. The chip of clause 12, wherein each of the first backside thermally conductive layer and the third backside thermally conductive layer comprises aluminum nitride.
14. The chip of clause 13, wherein each of the second backside thermally conductive layer and the fourth backside thermally conductive layer comprises silicon nitride or silicon carbon nitride.
15. The chip of any one of clauses 12 to 14, wherein a thickness of the first backside thermally conductive layer is approximately equal to a height of the first via, and a thickness of the third backside thermally conductive layer is approximately equal to a heigh of the second via.
16. The chip of clause 15, wherein a thickness of the second backside thermally conductive layer is approximately equal to a height of the first metal path, and a thickness of the fourth backside thermally conductive layer is approximately equal to a height of the second metal path.
17. The chip of any one of clauses 12 to 16, wherein the first via, the second via, the first metal path, and the second metal path are part of a backside power distribution network configured to provide the active device with a supply voltage.
18. A chip, comprising:
   an active device;
   a first backside thermally conductive layer;
   a first backside dielectric layer, wherein the first backside thermally conductive layer is between the active device and the first backside dielectric layer;
   a first via electrically coupled to the active device, wherein the first via extends through the first backside thermally conductive layer; and
   a first metal path electrically coupled to the first via, wherein the first metal path extends through the first backside dielectric layer.
19. The chip of clause 18, wherein the first backside thermally conductive layer comprises aluminum nitride.
20. The chip of clause 19, wherein the first backside dielectric layer comprises silicon oxide.
21. The chip of any one of clauses 18 to 20, wherein a thickness of the first backside thermally conductive layer is approximately equal to a height of the first via.
22. The chip of clause 21, wherein a thickness of the first backside dielectric layer is approximately equal to a height of the first metal path.
23. The chip of any one of clauses 18 to 22, wherein the first via and the first metal path are part of a backside power distribution network configured to provide the active device with a supply voltage.
24. The chip of clause 23, further comprising frontside signal routing electrically coupled to the active device.
25. The chip of clause 24, wherein the first via is electrically coupled to a first source/drain of the active device and the frontside signal routing is electrically coupled to a second source/drain of the active device.
26. The chip of clause 25, wherein the active device includes a gate and one or more channels passing through the gate and electrically coupled between the first source/drain and the second source/drain.
27. The chip of clause 26, wherein the one or more channels include one or more nanosheets or one or more fins.
28. The chip of any one of clauses 24 to 27, wherein the active device is between the frontside routing and the first backside thermally conductive layer.
29. The chip of any one of clauses 18 to 28, further comprising:
   a second backside thermally conductive layer;
   a second backside dielectric layer, wherein the second backside thermally conductive layer is between the first backside dielectric layer and the second backside dielectric layer;
   a second via electrically coupled to the first metal path, wherein the second via extends through the second backside thermally conductive layer; and
   a second metal path electrically coupled to the second via, wherein the second metal path extends through the second backside dielectric layer.
30. The chip of clause 29, wherein each of the first backside thermally conductive layer and the second backside thermally conductive layer comprises aluminum nitride.
31. The chip of clause 30, wherein each of the first backside dielectric layer and the second backside dielectric layer comprises silicon oxide.
32. The chip of any one of clauses 29 to 31, wherein a thickness of the first backside thermally conductive layer is approximately equal to a height of the first via, and a thickness of the second backside thermally conductive layer is approximately equal to a heigh of the second via.
33. The chip of clause 32, wherein a thickness of the second backside dielectric layer is approximately equal to a height of the first metal path, and a thickness of the second backside dielectric layer is approximately equal to a height of the second metal path.
34. The chip of any one of clauses 29 to 33, wherein the first via, the second via, the first metal path, and the second metal path are part of a backside power distribution network configured to provide the active device with a supply voltage.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value. For example, a thickness that is approximately equal to a height is a thickness that is within a range of 90 percent to 110 of the height. Within the present disclosure, “vertical routing” is routing in the z direction and “lateral routing” is routing in the x direction, y direction, or both.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element. At least one of A, B, and C means A, B, C, AB, BC, AC, or ABC.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
an active device;
a first backside thermally conductive layer;
a second backside thermally conductive layer, wherein the first backside thermally conductive layer is between the active device and the second backside thermally conductive layer;
a first via electrically coupled to the active device, wherein the first via extends through the first backside thermally conductive layer; and
a first metal path electrically coupled to the first via, wherein the first metal path extends through the second backside thermally conductive layer.

2. The chip of claim 1, wherein the first backside thermally conductive layer comprises aluminum nitride.

3. The chip of claim 2, wherein the second backside thermally conductive layer comprises silicon nitride or silicon carbon nitride.

4. The chip of claim 1, wherein a thickness of the first backside thermally conductive layer is approximately equal to a height of the first via.

5. The chip of claim 4, wherein a thickness of the second backside thermally conductive layer is approximately equal to a height of the first metal path.

6. The chip of claim 1, wherein the first via and the first metal path are part of a backside power distribution network configured to provide the active device with a supply voltage.

7. The chip of claim 1, further comprising:
a third backside thermally conductive layer;
a fourth backside thermally conductive layer, wherein the third backside thermally conductive layer is between the second backside thermally conductive layer and the fourth backside thermally conductive layer;
a second via electrically coupled to the first metal path, wherein the second via extends through the third backside thermally conductive layer; and
a second metal path electrically coupled to the second via, wherein the second metal path extends through the fourth backside thermally conductive layer.

8. The chip of claim 7, wherein each of the first backside thermally conductive layer and the third backside thermally conductive layer comprises aluminum nitride.

9. The chip of claim 8, wherein each of the second backside thermally conductive layer and the fourth backside thermally conductive layer comprises silicon nitride or silicon carbon nitride.

10. The chip of claim 7, wherein a thickness of the first backside thermally conductive layer is approximately equal to a height of the first via, and a thickness of the third backside thermally conductive layer is approximately equal to a heigh of the second via.

11. A chip, comprising:
an active device;
a first backside thermally conductive layer;
a first backside dielectric layer, wherein the first backside thermally conductive layer is between the active device and the first backside dielectric layer;
a first via electrically coupled to the active device, wherein the first via extends through the first backside thermally conductive layer; and
a first metal path electrically coupled to the first via, wherein the first metal path extends through the first backside dielectric layer.

12. The chip of claim 11, wherein the first backside thermally conductive layer comprises aluminum nitride.

13. The chip of claim 12, wherein the first backside dielectric layer comprises silicon oxide.

14. The chip of claim 11, wherein a thickness of the first backside thermally conductive layer is approximately equal to a height of the first via.

15. The chip of claim 14, wherein a thickness of the first backside dielectric layer is approximately equal to a height of the first metal path.

16. The chip of claim 11, wherein the first via and the first metal path are part of a backside power distribution network configured to provide the active device with a supply voltage.

17. The chip of claim 11, further comprising:
a second backside thermally conductive layer;
a second backside dielectric layer, wherein the second backside thermally conductive layer is between the first backside dielectric layer and the second backside dielectric layer;
a second via electrically coupled to the first metal path, wherein the second via extends through the second backside thermally conductive layer; and
a second metal path electrically coupled to the second via, wherein the second metal path extends through the second backside dielectric layer.

18. The chip of claim 17, wherein each of the first backside thermally conductive layer and the second backside thermally conductive layer comprises aluminum nitride.

19. The chip of claim 18, wherein each of the first backside dielectric layer and the second backside dielectric layer comprises silicon oxide.

20. The chip of claim 17, wherein a thickness of the first backside thermally conductive layer is approximately equal to a height of the first via, and a thickness of the second backside thermally conductive layer is approximately equal to a heigh of the second via.
